(19) United States
(12) Patent Application Publication
(10) Pub. No.: US 2026/0363132 A1
(43) Pub. Date: Nov. 12, 2026

(54) SEMICONDUCTOR PACKAGE AND ELECTRONIC DEVICE INCLUDING SAME

(71) Applicant: Samsung Electronics Co., Ltd., Suwon-si (KR)

(72) Inventors: Soomoon PARK, Suwon-si (KR); Hyung-Sun JANG, Suwon-si (KR)

(73) Assignee: Samsung Electronics Co., Ltd., Suwon-si (KR)

(21) Appl. No.: 19/371,539

(22) Filed: Oct. 28, 2025

(30) Foreign Application Priority Data
May 9, 2025 (KR) 10-2025-0060095

(51) Int. Cl. H10W 74/10; H10W 70/40; H10W 90/00

(52) U.S. Cl. CPC H10W 74/124; H10W 70/415; H10W 90/726

(57) ABSTRACT

A semiconductor package includes a lead frame including a die pad and a first lead terminal spaced apart from a first side of the die pad, a semiconductor chip on the lead frame, and a mold part at least partially covering the lead frame and the semiconductor chip, and exposing a lower surface of the first lead terminal. The mold part includes a first stepped portion that is recessed from a lower surface of the mold part and is configured to expose a first side surface of the first lead terminal, and the first stepped portion has a plurality of stepped surfaces.

### CROSS-REFERENCE TO RELATED APPLICATION

This U.S. non-provisional application claims priority under 35 U.S.C. § 119 to Korean Patent Application No. 10-2025-0060095, filed in the Korean Intellectual Property Office on May 9, 2025, the entire contents of which are hereby incorporated by reference.

### BACKGROUND

Some example embodiments relate to a semiconductor package and to an electronic device including the semiconductor package.

As electronic devices become lighter and provide higher performance, it is beneficial for semiconductor packages to also be miniaturized and improve in performance. Semiconductor packages in which a semiconductor chip is mounted on a lead frame are currently being researched in order to miniaturize the semiconductor package, reduce weight, improve performance, increase capacity, and improve reliability of semiconductor packages.

It may be advantageous for the semiconductor package to have a structure that may reduce or prevent deformation or damage that may be caused to the semiconductor package due to external impact or temperature change.

### SUMMARY

Some example embodiments of the present disclosure may provide a semiconductor package having improved reliability and an electronic device including the semiconductor package.

According to some example embodiments of the present disclosure, a semiconductor package may include a lead frame including a die pad and a first lead terminal spaced apart from one side of the die pad, a semiconductor chip disposed on the lead frame, and a mold part covering the lead frame and the semiconductor chip, and exposing a lower surface of the first lead terminal, wherein the mold part includes a first stepped portion recessed from a lower surface of the mold part to expose a first side surface of the first lead terminal, and the first stepped portion has a plurality of stepped surfaces.

According to some example embodiments of the present disclosure, a semiconductor package may include a lead frame including a die pad and a plurality of lead terminals disposed at one side of the die pad and spaced apart from each other, a semiconductor chip disposed on the lead frame, and a mold part disposed on the lead frame and the semiconductor chip, and exposing a lower surface of each of the plurality of lead terminals, wherein the mold part includes a first stepped surface having a first step with respect to the lower surface of the mold part and formed around the plurality of lead terminals, and a second stepped surface having a second step with respect to the first stepped surface and contacting a side surface of at least one of the plurality of lead terminals.

According to some example embodiments of the present disclosure, an electronic device may include a substrate including a plurality of connection pads, a semiconductor package mounted on the substrate, and a plurality of joints connecting the substrate and the semiconductor package, wherein the semiconductor package includes a lead frame including a die pad and a plurality of lead terminals spaced apart from one side of the die pad, a semiconductor chip mounted on the lead frame, and a mold part covering the lead frame and the semiconductor chip, wherein the mold part includes a first stepped surface having a first step with respect to lower surfaces of the plurality of lead terminals and formed around the plurality of lead terminals, and a second stepped surface having a second step with respect to the first stepped surface and contacting a side surface of at least one of the plurality of lead terminals, and at least some of the plurality of joints are positioned at a level higher than the first stepped surface.

According to some example embodiments of the present disclosure, because a stepped portion is formed around the lead terminal so that a bonding area between the lead terminal and solder is increased, reliability of the semiconductor package may be improved.

### BRIEF DESCRIPTION OF THE DRAWINGS

FIG. 1 is a perspective view illustrating a semiconductor package according to some example embodiments of the present disclosure.

FIG. 2 is a perspective view illustrating a lower surface of the semiconductor package according to some example embodiments of the present disclosure.

FIG. 3 is a cross-sectional view illustrating a section taken along line A-A′ of FIG. 1.

FIG. 4 illustrates a lower surface of the semiconductor package according to some example embodiments of the present disclosure.

FIG. 5 is a front view illustrating one side of the semiconductor package according to some example embodiments of the present disclosure.

FIG. 6 is an enlarged view illustrating a portion of FIG. 5.

FIGS. 7 and 8 illustrate the semiconductor package according to some example embodiments of the present disclosure.

FIG. 9 illustrates the semiconductor package according to some example embodiments of the present disclosure.

FIGS. 10 and 11 illustrate the semiconductor package according to some example embodiments of the present disclosure.

FIG. 12 illustrates a part of an electronic device including the semiconductor package according to some example embodiments of the present disclosure.

FIGS. 13, 14, 15, and 16 illustrate a manufacturing method of the semiconductor package according to some example embodiments of the present disclosure.

FIGS. 17 and 18 illustrate a manufacturing method of the semiconductor package according to some example embodiments of the present disclosure.

### DETAILED DESCRIPTION OF EXAMPLE EMBODIMENTS

Hereinafter, with reference to the drawings, semiconductor packages according to some example embodiments of the present disclosure and electronic devices including the semiconductor packages will be described in detail.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

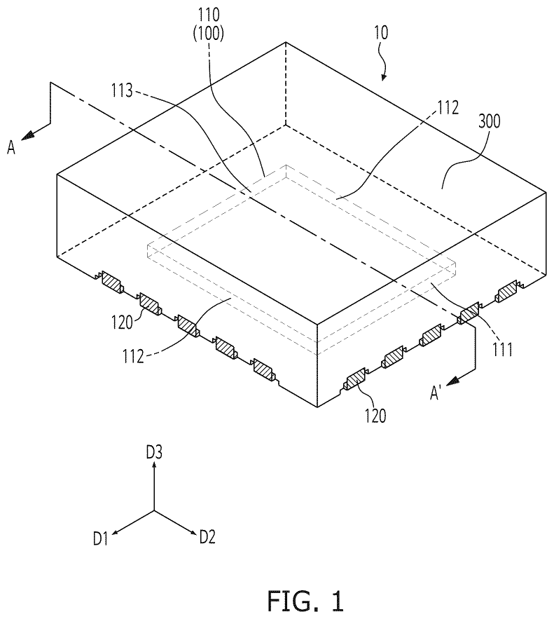

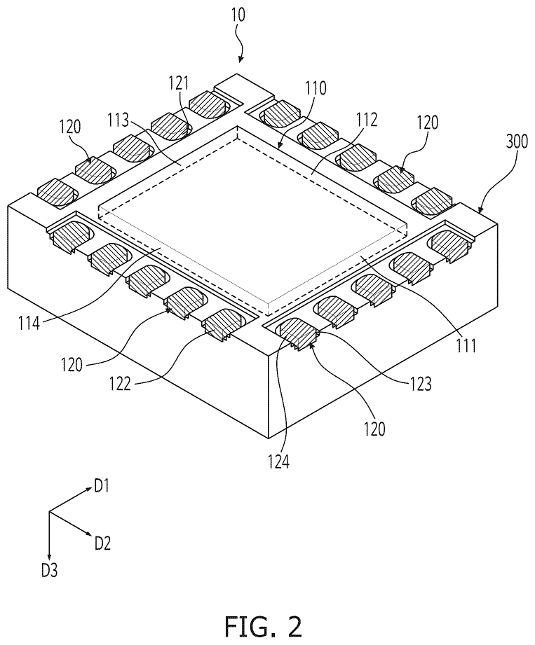

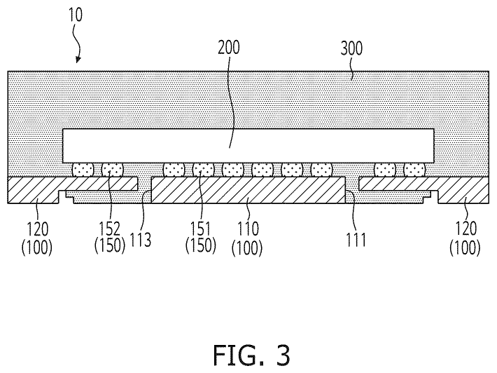

FIG. 1 is a perspective view illustrating a semiconductor package according to some example embodiments of the present disclosure. FIG. 2 is a perspective view illustrating a lower surface of the semiconductor package according to some example embodiments of the present disclosure. FIG. 3 is a cross-sectional view illustrating a section taken along line A-A′ of FIG. 1.

Referring to FIGS. 1 to 3, a semiconductor package 10, according to some example embodiments of the present disclosure, may include a lead frame 100, a plurality of solder bumps 150, a semiconductor chip 200, and a mold part 300. Hereinafter, a first direction D1 and a second direction D2 may be directions parallel to a lower surface of the semiconductor package 10, and the first direction D1 and the second direction D2 may be orthogonal to each other. A third direction D3 is a height direction of the semiconductor package 10 and may be orthogonal to each of the first direction D1 and the second direction D2.

The semiconductor package 10 is described, for example, as a Flip Chip Quad Flat No-lead (FCQFN) package in which the semiconductor chip 200 is mounted on the lead frame 100 in a flip-die configuration. However, example embodiments of the present disclosure are not limited thereto and may be widely applied to various types of packages in which the semiconductor chip is mounted on a lead frame, such as Dual Flat No-lead (DFN) packages and Quad Flat No-lead (QFN) packages. For example, the semiconductor chip 200 and the lead frame 100 may be connected by wire bonding.

The semiconductor package 10 may have a hexahedral outer shape. A lower surface of the semiconductor package 10 may serve as a mounting surface of the semiconductor package 10. For example, the semiconductor package 10 may be mounted such that the lower surface faces an upper surface of a board (e.g., a printed circuit board (PCB)).

The lower surface of the semiconductor package 10 may have a rectangular shape with four corners. In an embodiment, the lower surface of the semiconductor package 10 may have a square shape. However, example embodiments are not limited thereto, and the lower surface of the semiconductor package 10 may have a rectangular shape or any other shape. A portion of the lead frame 100 may be arranged to be exposed to the outside of the semiconductor package 10.

The lead frame 100 may be formed of or include a metal or a metal alloy and may have a predetermined (or desired or given) thickness. For example, the lead frame 100 may be formed of copper or a copper alloy and may be formed by cutting, stamping, or etching. In some example embodiments, a surface of the lead frame 100 may be plated with tin.

The lead frame 100 may provide a region to which the plurality of solder bumps 150 are attached. The lead frame 100 may be divided into a plurality of regions. For example, the lead frame 100 may include a region for heat dissipation and a region functioning as input/output terminals.

The lead frame 100 may include a die pad 110 and a plurality of lead terminals 120. The die pad 110 may have a rectangular plate shape having four side surfaces. For example, the die pad 110 may have first to fourth side surfaces 111-114. In some example embodiments, the plurality of lead terminals 120 may be connected to the die pad 110, for example, via the solder bumps 150 and semiconductor chip 200.

The plurality of lead terminals 120 may be spaced apart from side surfaces of the die pad 110. The plurality of lead terminals 120 may be arranged to be spaced apart from each other so as not to be electrically shorted or connected. The plurality of lead terminals 120 may be arranged along a side of the die pad 110. For example, the plurality of lead terminals 120 may be arranged along the first to fourth side surfaces 111 to 114 of the die pad 110. FIGS. 1, 2, and 3 illustrate some example embodiments in which five lead terminals 120 are arranged along one corner of the semiconductor package 10. However, example embodiments are not limited thereto and may the semiconductor package 10 may be modified to include different number, position, and/or arrangement of the lead terminals 120.

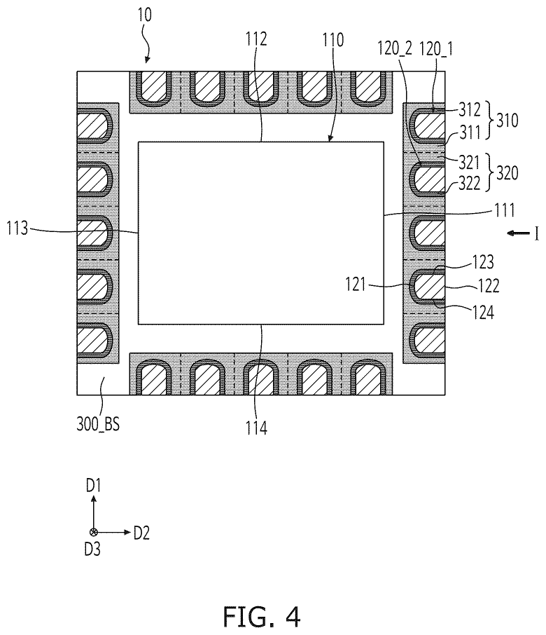

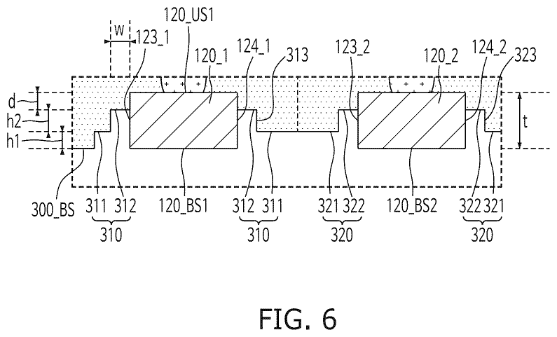

One or more of the plurality of lead terminals 120 may generally form or otherwise define the outer shape of the semiconductor package 10. One or more surfaces of the plurality of lead terminals 120 may be exposed to the outside of the semiconductor package 10. For example, a second surface 122 (FIG. 4) and lower surfaces, for example, surfaces 120BS1 and 120BS2 (FIG. 6) of the plurality of lead terminals 120 may be exposed to the outside of the semiconductor package 10. For the purposes of discussion herein, a surface (or any portion thereof) of a lead terminal 120 (or the package 10) is considered as being exposed when the mold part 300 is not formed (or does not overlap) the surface of the lead terminal 120.

The plurality of solder bumps 150 may be disposed on the lead frame 100. The plurality of solder bumps 150 may include first solder bumps 151 and second solder bumps 152. The first solder bumps 151 may be disposed on the die pad 110, and the second solder bumps 152 may be disposed on the lead terminals 120.

The semiconductor chip 200 may be mounted on the lead frame 100 by means of the plurality of solder bumps 150. The first solder bumps 151 and the second solder bumps 152 may be disposed between the lead frame 100 and the semiconductor chip 200. For example, the first solder bumps 151 may be disposed between an upper surface of the die pad 110 and a lower surface of the semiconductor chip 200, and the second solder bumps 152 may be disposed between an upper surface of the plurality of lead terminals 120 and the lower surface of the semiconductor chip 200.

The semiconductor chip 200 may be a logic semiconductor chip, a modem chip, or a memory semiconductor chip. For example, the semiconductor chip 200 may include a central processing unit (CPU), a graphics processing unit (GPU), and/or a modem. For example, the semiconductor chip 200 may be implemented as a modem die supporting a Wideband Code Division Multiple Access (WCDMA) communication scheme, but is not limited thereto. Alternatively, the semiconductor chip 200 may be a volatile memory chip such as a dynamic random access memory (DRAM) or a static random access memory (SRAM), or a nonvolatile memory chip such as a phase-change random access memory (PRAM), a magnetoresistive random access memory (MRAM), a ferroelectric random access memory (FeRAM), or a resistive random access memory (RRAM).

The mold part 300 may be formed to cover the lead frame 100 and the semiconductor chip 200 with a predetermined (or desired or given) thickness. The mold part 300 may cover side surfaces and upper surfaces of the lead frame 100, the semiconductor chip 200, and the plurality of solder bumps 150. The mold part 300 may be located between solder bumps 150. For the purposes of discussion herein, the mold part 300 is considered as covering a component of the semiconductor package 10 when the mold part 300 is in contact or formed on with the component or at least a portion thereof. The mold part 300 may include, for example, an epoxy mold compound (EMC), but is not limited thereto.

In some example embodiments, a lower surface of the die pad 110 may be exposed to the outside of the semiconductor package 10. In some example embodiments, the mold part 300 may be formed on the lower surface of the die pad 110 so that the lower surface of the die pad 110 may not be exposed to the outside of the semiconductor package 10.

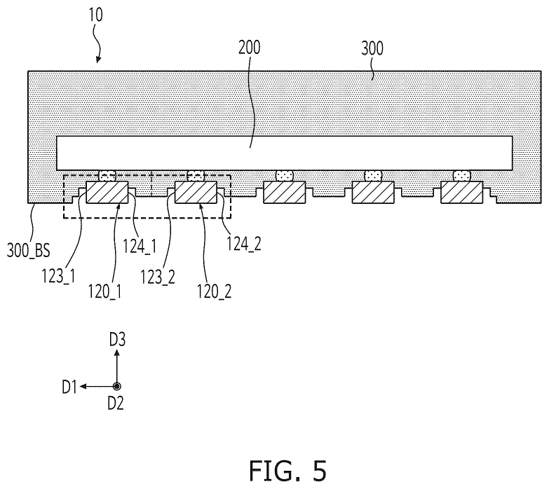

FIG. 4 illustrates a lower surface of the semiconductor package according to some example embodiments of the present disclosure. FIG. 5 is a front view illustrating one side of the semiconductor package according to some example embodiments of the present disclosure. FIG. 6 is an enlarged view illustrating a portion of FIG. 5. FIG. 5 is a view as seen in direction I of FIG. 4.

Referring to FIGS. 4 to 6, each lead terminal of the plurality of lead terminals 120 may include a first surface 121, a second surface 122, a third surface 123, and a fourth surface 124. The first surface 121, the second surface 122, the third surface 123, and the fourth surface 124 may be or otherwise define the four side surfaces of each of the plurality of lead terminals 120.

In some example embodiments, each lead terminal 120 may include an upper portion which contacts the second solder bumps 152 and which supports the second solder bumps 152, and a lower portion on which the mold part 300 is not formed and is thereby exposed. The first surface 121, the second surface 122, the third surface 123, and the fourth surface 124 may be or define the four side surfaces surrounding the lower portion of each of the plurality of lead terminals 120.

The first surface 121 may be defined as a surface facing a side surface of the die pad 110, and the second surface 122 may be defined as a surface opposite to the first surface 121. For example, the first surface 121 may be considered as an inner surface of the lead terminal 120 and the second surface 122 may be considered as an outer surface of the lead terminal 120. In some example embodiments, the first surface 121 may have a curved shape, but is not limited thereto. The first surface 121 may have a planar shape parallel to the second surface 122.

The third surface 123 and the fourth surface 124 may be surfaces other than the first surface 121 and the second surface 122 among the four side surfaces of each of the plurality of lead terminals 120. The third surface 123 and the fourth surface 124 may be referred to as a first side surface 123 and a second side surface 124, respectively. The third surface 123 and the fourth surface 124 may be opposite to each other. The third surface 123 and the fourth surface 124 may thus connect the first surface 121 and the second surface 122 to each other.

The plurality of lead terminals 120 may include a first lead terminal 120_1 and a second lead terminal 120_2. Hereinafter, the plurality of lead terminals 120 will be described with reference to the first lead terminal 120_1 and the second lead terminal 120_2.

The first lead terminal 120_1 and the second lead terminal 120_2 may be disposed at or along one side of the die pad 110. For example, the first lead terminal 120_1 and the second lead terminal 120_2 may be arranged along the first surface 111 of the die pad 110. The first lead terminal 120_1 may include a first surface 121_1 and a second surface 122_1 opposite the first surface 121_1. The first surface 121_1 and the second surface 122_1 of the lead terminal 120_1 may correspond to the first surface 121 and the second surface 122, respectively, of the lead terminal 120. The second lead terminal 120_2 may include a first surface 121_2 and a second surface 122_2 opposite the first surface 121_2. The first surface 121_2 and the second surface 122_2 of the lead terminal 120_2 may correspond to the first surface 121 and the second surface 122, respectively, of the lead terminal 120. The first lead terminal 120_1 may include a third surface 123_1 (or first side surface 123_1) and a fourth surface 124_1 (or second side surface 124_1) opposite the third surface 123_1. The third surface 123_1 and the fourth surface 124_1 of the lead terminal 120_1 may correspond to the third surface 123 and the fourth surface 124, respectively, of the lead terminal 120. The second lead terminal 120_2 may include a third surface 123_2 (or first side surface 123_2) and a fourth surface 124_2 (or second side surface 124_2) opposite the third surface 123_2. The third surface 123_2 and the fourth surface 124_2 of the lead terminal 120_2 may correspond to the third surface 123 and the fourth surface 124, respectively, of the lead terminal 120. The first lead terminal 120_1 and the second lead terminal 120_2 may be spaced apart from each other. For example, the second lead terminal 120_2 may be spaced apart from the second side surface 124_1 of the first lead terminal 120_1. In other words, in the first direction D1, the second side surface 124_1 of the first lead terminal 120_1 and the first side surface 123_2 of the second lead terminal 120_2 may be arranged to face each other.

The mold part 300 may include a first stepped portion 310 and a second stepped portion 320. For example, the first stepped portion 310 may expose one or more side surfaces of the first lead terminal 120_1, and the second stepped portion 320 may expose one or more side surfaces of the second lead terminal 120_2.

The first stepped portion 310 and the second stepped portion 320 may be formed recessed from a lower surface 300_BS of the mold part 300. For example, the first stepped portion 310 and the second stepped portion 320 may be regions of the mold part 300 in which a part of the mold part 300 is recessed.

The first stepped portion 310 and the second stepped portion 320 may have a plurality of stepped surfaces. In some example embodiments of the present disclosure, the first stepped portion 310 and the second stepped portion 320 are described as having two steps, but are not limited thereto. In some example embodiments, the first stepped portion 310 and the second stepped portion 320 may have two or more steps. For example, the first stepped portion 310 and the second stepped portion 320 may include two or more stepped surfaces. For the purposes of discussion herein, a configuration that has n stepped surfaces may mean that the configuration has n surfaces having different vertical levels with respect to a given reference plane. In some example embodiments, the given reference plane may be the lower surface 300_BS of the mold part 300, but is not limited thereto.

The first stepped portion 310 may include a first stepped surface 311, a second stepped surface 312, and a first connecting surface 313 that connects the first stepped surface 311 and the second stepped surface 312. The first stepped portion 310 may expose a first side surface 123_1 and a second side surface 124_1 of the first lead terminal 120_1. In some example embodiments, the first stepped portion 310 may further expose the first surface 121_1 of the first lead terminal 120_1.

The first stepped surface 311 may have a first step h1 with respect to the lower surface 300_BS of the mold part 300. The first stepped surface 311 may be spaced upward (e.g., with respect to the orientation in FIG. 6) by the first step h1 from the lower surface 300_BS of the mold part 300. The first stepped surface 311 may be formed around the first lead terminal 120_1. The first stepped surface 311 may be spaced apart from side surfaces (e.g., one or more surfaces 121_1, 123_1, 124_1) of the first lead terminal 120_1. For example, the first stepped surface 311 may be spaced apart from the first surface 121_1, the first side surface 123_1, and the second side surface 124_1 of the first lead terminal 120_1. In a plan view, the first stepped surface 311 may partially surround (or may be arranged adjacent to) the first surface 121_1, the first side surface 123_1, and the second side surface 124_2 of the first lead terminal 120_1.

The second stepped surface 312 may have a second step h2 with respect to the first stepped surface 311. The second stepped surface 312 may be spaced upward (e.g., with respect to the orientation in FIG. 6) by the second step h2 from the first stepped surface 311. The second stepped surface 312 may contact a side surface of the first lead terminal 120_1. The second stepped surface 312 may contact the first side surface 123_1 and the second side surface 124_1 of the first lead terminal 120_1.

In a plan view, the second stepped surface 312 may partially surround (or may be arranged adjacent to) a part of the first lead terminal 120_1. The second stepped surface 312 may extend along a part of the side surfaces of the first lead terminal 120_1. The second stepped surface 312 may be positioned between the first lead terminal 120_1 and the first stepped surface 311, for example, in the first direction D1. For example, the second stepped surface 312 may extend along a second surface 122_2, a first side surface 123_2, and a second side surface 124_2 of the second lead terminal 120_2. In some example embodiments, the second stepped surface 312 may surround all four side surfaces of the first lead terminal 120_1.

The first connecting surface 313 may connect the first stepped surface 311 and the second stepped surface 312. The first connecting surface 313 may be provided perpendicular to each of the first stepped surface 311 and the second stepped surface 312. The first connecting surface 313 may have a height corresponding to the second step h2. In some example embodiments, the first connecting surface 313 may be provided so as to form a predetermined (or desired or given) angle with each of the first stepped surface 311 and the second stepped surface 312. In some example embodiments, the angle may be 90° or an angle other than 90°.

The second stepped portion 320 may include a third stepped surface 321, a fourth stepped surface 322, and a second connecting surface 323 connecting the third stepped surface 321 and the fourth stepped surface 322. The second stepped portion 320 may expose a first side surface 123_2 and a second side surface 124_2 of the second lead terminal 120_2. In some example embodiments, the second stepped portion 320 may further expose the first surface of the second lead terminal 120_2.

The third stepped surface 321 may have the first step h1 with respect to the lower surface 300_BS of the mold part 300. The third stepped surface 321 may be spaced upward (e.g., with respect to the orientation in FIG. 6) by the first step h1 from the lower surface 300_BS of the mold part 300. The third stepped surface 321 may be located on substantially the same plane (or substantially coplanar) as the first stepped surface 311 of the first stepped portion 310. The third stepped surface 321 may be connected to the first stepped surface 311 of the first stepped portion 310. As illustrated in FIG. 5, the first step h1 may be defined in the mold part 300 adjacent to the outermost lead terminals 120 (e.g., the lead terminals 120 on opposite ends in the first direction D1) and adjacent to a side surface of each outermost lead terminal. For example, the first step h1 is formed adjacent the first side surface 123_1 of the lead terminal 120_1, which is one of the outermost lead terminals 120 in the first direction D1.

The fourth stepped surface 322 may have the second step h2 with respect to the third stepped surface 321. The fourth stepped surface 322 may be spaced upward (e.g., with respect to the orientation in FIG. 6) by the second step h2 from the third stepped surface 321. The fourth stepped surface 322 may contact a side surface of the second lead terminal 120_2. The fourth stepped surface 322 may contact the first side surface 123_2 and the second side surface 124_2 of the second lead terminal 120_2. The fourth stepped surface 322 may be located on substantially the same plane (or may be substantially coplanar) as the second stepped surface 312 of the first stepped portion 310. In some example embodiments, each of the third stepped surface 321 and the fourth stepped surface 322 may be located at a different level from each of the first stepped surface 311 and the second stepped surface 312.

In a plan view, the fourth stepped surface 322 may surround a part of the second lead terminal 120_2. The fourth stepped surface 322 may extend along a part of the side surfaces of the second lead terminal 120_2. The fourth stepped surface 322 may be positioned between the second lead terminal 120_2 and the third stepped surface 321. For example, the fourth stepped surface 322 may extend along a first surface 121_2, a first side surface 123_2, and a second side surface 124_2 of the second lead terminal 120_2. In some example embodiments, the fourth stepped surface 322 may surround all four side surfaces of the second lead terminal 120_2.

The second connecting surface 323 may connect the third stepped surface 321 and the fourth stepped surface 322. The second connecting surface 323 may be provided perpendicular to each of the third stepped surface 321 and the fourth stepped surface 322. The second connecting surface 323 may have a height corresponding to the second step h2. In some example embodiments, the second connecting surface 323 may form a predetermined (or desired or given) angle with each of the third stepped surface 321 and the fourth stepped surface 322. In some example embodiments, the angle may be 90° or an angle other than 90°.

Referring to FIG. 6, the first stepped surface 311 and the second stepped surface 312 may be parallel to the lower surface 300_BS of the mold part 300. The first stepped surface 311 and the second stepped surface 312 may be parallel to the lower surface 120_BS1 of the first lead terminal 120_1. The first stepped surface 311 and the second stepped surface 312 may be perpendicular to the first side surface 123_1 of the first lead terminal 120_1. For example, the first stepped surface 311 and the second stepped surface 312 may have a flat shape or planar shape. In some example embodiments, one or more of the first stepped surface 311 and the second stepped surface 312 may include bends or irregularities. In some example embodiments, one or more of the first stepped surface 311 and the second stepped surface 312 may include curved surfaces or inclined surfaces.

The first lead terminal 120_1 may have a predetermined (or desired or given) thickness t. For example, the thickness t of the first lead terminal 120_1 may be 200 μm (or about 200 μm). However, the example embodiments are not limited thereto, and the thickness t of the first lead terminal 120_1 may be greater than 200 μm or less than 200 μm depending on application and/or design.

A distance between the lower surface 300_BS of the mold part 300 and the first stepped surface 311 may be defined as the first step h1. For example, the first stepped surface 311 may have the first step h1 with respect to the lower surface 300_BS of the mold part 300. The first step h1 may be less than half of the thickness t of the first lead terminal 120_1. For example, the first step h1 may be greater than or equal to 1 μm (or about 1 μm) and less than or equal to 100 μm (or about 100 μm).

A distance between the first stepped surface 311 and the second stepped surface 312 may be defined as the second step h2. The second stepped surface 312 may have the second step h2 with respect to the first stepped surface 311. For example, the second step h2 may be greater than or equal to 1 μm and less than or equal to 100 μm.

The second stepped surface 312 may be positioned at a level lower (e.g., with respect to the orientation in FIG. 6) than an upper surface 120_US1 of the first lead terminal 120_1. The second stepped surface 312 may be positioned lower than the upper surface 120_US1 of the first lead terminal 120_1. The second stepped surface 312 may have a predetermined distance d from the upper surface 120_US1 of the first lead terminal 120_1. For example, the distance d between the second stepped surface 312 and the upper surface 120_US1 of the first lead terminal 120_1 may be 1 μm (or about 1 μm). In other words, a sum of the first step h1 and the second step h2 may be less than the thickness t of the first lead terminal 120_1.

In addition, a distance between the lower surface 300_BS of the mold part 300 and the second stepped surface 312 may be greater than or equal to 101 μm and less than or equal to 199 μm. However, example embodiments are not limited thereto, and the distance between the second stepped surface 312 and the upper surface 120_US1 of the first lead terminal 120_1 may vary depending on application and/or design.

When the semiconductor package is mounted on a board, solder paste may flow into the second stepped surface 312. Accordingly, the second stepped surface 312 may have a predetermined width w. For example, the width of the second stepped surface 312 may be approximately 50 μm. In some example embodiments, the width w of the second stepped surface 312 may be greater than a width of the first stepped surface 311. However, example embodiments of the present disclosure are not limited thereto, and the width of the second stepped surface 312 may be provided in various sizes.

The semiconductor package 10 increases an area where solder paste is bonded during board mounting because the lower surface 120_BS1 of the first lead terminal 120_1 and the side surfaces 123_1 and 124_1 of the first lead terminal 120_1 are exposed, and as a result product reliability may be improved.

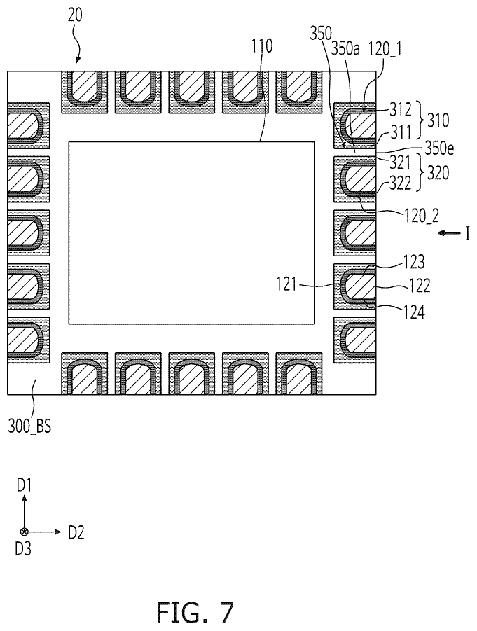

Hereinafter, example embodiments are described with reference to FIGS. 7-12 and may be best understood with reference thereto where like numerals indicate like elements not described again in detail.

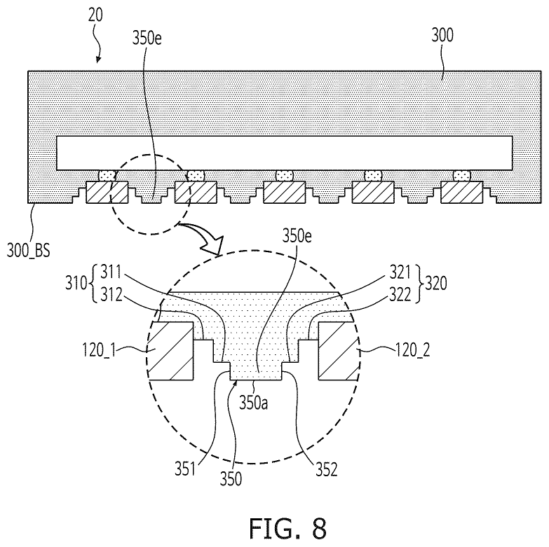

FIGS. 7 and 8 illustrate the semiconductor package according to some example embodiments of the present disclosure. FIG. 8 is a view as seen in direction I of FIG. 7.

Referring to FIGS. 7 and 8, in a semiconductor package 20, according to some example embodiments of the present disclosure, the mold part 300 may further include a protrusion 350. In some example embodiments of the present disclosure, description will be given based on the first and second lead terminals 120_1 and 120_2 and the first and second stepped portions 310 and 320. The following description may be equally applied to other ones of the plurality of lead terminals 120 and stepped portions.

The protrusion 350 may partition the first stepped portion 310 and the second stepped portion 320. The protrusion 350 may be provided between the first stepped portion 310 and the second stepped portion 320. For example, the protrusion 350 may provide (or otherwise define) a boundary between the first stepped portion 310 and the second stepped portion 320. The protrusion 350 may be spaced apart from each of the first lead terminal 120_1 and the second lead terminal 120_2.

The protrusion 350 may extend in the second direction D2 perpendicular to a direction in which the first lead terminal 120_1 and the second lead terminal 120_2 are spaced apart. An end 350e of the protrusion 350 may be located on the same plane (e.g., coplanar) as the second surface 122_1 of the first lead terminal 120_1. In some example embodiments, in a plan view, the end 350e of the protrusion 350 may be located inside or spaced from the lower surface of the semiconductor package 20.

The protrusion 350 may include a protrusion surface 350a, a first side surface 351, and a second side surface 352.

The protrusion surface 350a may be located on the same plane (e.g., coplanar) as the lower surfaces of the plurality of lead terminals 120. In some example embodiments, the protrusion surface 350a may be located on the same plane (e.g., coplanar) as the lower surface 300_BS of the mold part 300. The protrusion surface 350a may be a part of the lower surface 300_BS of the mold part 300. Each of the first stepped surface 311 and the third stepped surface 321 may have a step with respect to the protrusion surface 350a. In some example embodiments, a width of the protrusion surface 350a may be greater than widths of the first stepped surface 311 and the second stepped surface 312. The first side surface 351 of the protrusion 350 may face the second side surface 124_1 of the first lead terminal 120_1. The second side surface 352 of the protrusion 350 may face the first side surface 123_2 of the second lead terminal 120_2. In some example embodiments, each of the first side surface 351 and the second side surface 352 of the protrusion 350 may be inclined.

The protrusion 350 may be a remaining portion of the mold part 300 where a part of the mold part 300 is not removed. For example, the protrusion 350 may be formed by removing peripheral regions except the protrusion 350 while removing a part of the mold part 300. For example, the protrusion surface 350a may have a planar shape. However, in some example embodiments, the protrusion surface 350a may have other shapes such as a curved shape that may be obtained by appropriately removing portions of the protrusion 350. In some example embodiments, the protrusion 350 may be provided on each of the first stepped surface 311 and the third stepped surface 321 of the mold part 300 between adjacent lead terminals 120.

Because a relatively lesser region of the mold part 300 may be removed when the first stepped surface 311 and the second stepped surface 312 are formed (in order to form the protrusion 350), the semiconductor package 20 may reduce process time and/or process cost.

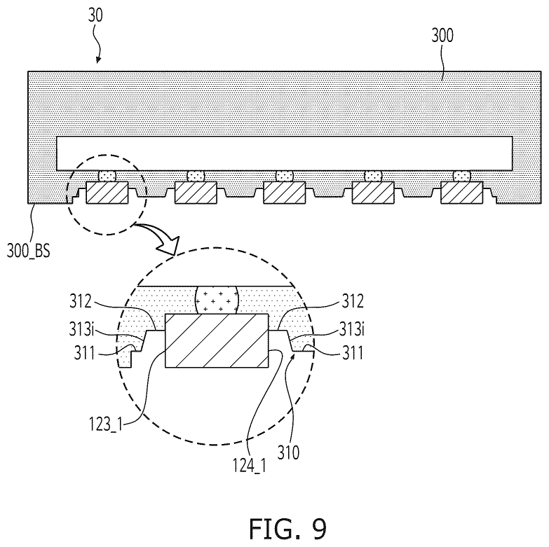

FIG. 9 illustrates a part of an electronic device including the semiconductor package 30 according to some example embodiments of the present disclosure.

Referring to FIG. 9, in a semiconductor package 30, the mold part 300 may include an inclined surface 313i. In the some example embodiments of the present disclosure, description will be given based on the first lead terminal 120_1 and the first stepped portion 310. The following description may be equally applied to other ones of the plurality of lead terminals 120 and stepped portions.

The inclined surface 313i may be provided between the first stepped surface 311 and the second stepped surface 312. The inclined surface 313i may inclinedly connect the first stepped surface 311 and the second stepped surface 312. The inclined surface 313i may form a predetermined (or desired or given) angle with each of the first stepped surface 311 and the second stepped surface 312.

The inclined surface 313i may be inclined (e.g., with respect to the orientation in FIG. 9) in a direction approaching the first lead terminal 120_1 or the direction of semiconductor chip 200 as the inclined surface 313i becomes distant from or extends away from the first stepped surface 311. For example, the inclined surface 313i may be inclined in a direction approaching the first side surface 123_1 and the second side surface 124_1 of the first lead terminal 120_1 as the inclined surface 313i extends away from the first stepped surface 311. The inclined surface 313i may be provided with a constant inclination or slope. In some example embodiments, the inclined surface 313i may have a convex shape or a convex shape.

Because the inclined surface 313i is provided between the first stepped surface 311 and the second stepped surface 312, the semiconductor package 30 may limit or prevent the first stepped surface 311 from collapsing when the second stepped surface 312 is formed. As a result, the inclined surface 313i may improve the structural integrity of the semiconductor package 30.

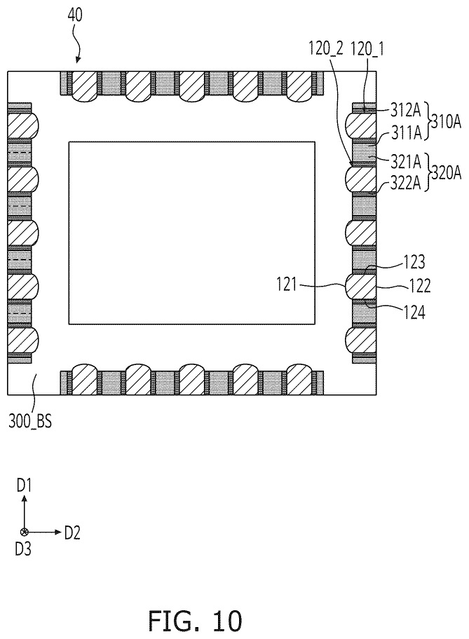

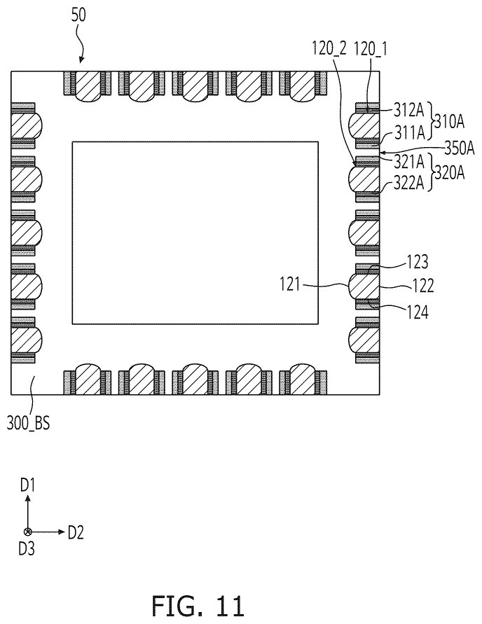

FIGS. 10 and 11 are drawings illustrating a part of an electronic device including the semiconductor package according to some example embodiments of the present disclosure.

Referring to FIG. 10, in a semiconductor package 40 according to some example embodiments of the present disclosure, shapes of a first stepped portion 310A and a second stepped portion 320A may be different from those of the embodiments of FIGS. 4 and 7.

The first stepped portion 310A may include a first stepped surface 311A and a second stepped surface 312A. The first stepped portion 310A may expose a first side surface 123_1 and a second side surface 124_1 of the first lead terminal 120_1. For example, the first stepped portion 310A may not expose the first surface 121_1 of the first lead terminal 120_1. The first stepped surface 311A and the second stepped surface 312A may not be connected to each other. The first stepped surface 311A and the second stepped surface 312A may be spaced apart from each other.

In a plan view, the second stepped surface 312A may partially surround (or may be disposed adjacent to) a part of the first lead terminal 120_1. The second stepped surface 312A may extend along a part of the side surfaces of the first lead terminal 120_1. The second stepped surface 312A may be positioned between the first lead terminal 120_1 and the first stepped surface 311A. For example, the second stepped surface 312A may extend along the first side surface 123 and the second side surface 124 of the first lead terminal 120_1.

The second stepped portion 320A may include a third stepped surface 321A and a fourth stepped surface 322A. The second stepped portion 320A may expose a first side surface 123_2 and a second side surface 124_2 of the second lead terminal 120_2. For example, the second stepped portion 320A may not expose the first surface 121_2 of the second lead terminal 120_2. The third stepped surface 321A and the fourth stepped surface 322A may not be connected to each other. The third stepped surface 321A and the fourth stepped surface 322A may be spaced apart from each other.

In a plan view, the fourth stepped surface 322A may partially surround (or may be disposed adjacent to) a part of the second lead terminal 120_2. The fourth stepped surface 322A may extend along a part of the side surfaces of the second lead terminal 120_2. The fourth stepped surface 322A may be positioned between the second lead terminal 120_2 and the third stepped surface 321A. For example, the fourth stepped surface 322A may extend along the first side surface 123_2 and the second side surface 124_2 of the second lead terminal 120_2.

Referring to FIG. 11, a semiconductor package 50, according to some example embodiments of the present disclosure may further include a protrusion 350A.

The protrusion 350A may partition the first stepped portion 310A and the second stepped portion 320A. The protrusion 350A may be provided between the first stepped portion 310A and the second stepped portion 320A. For example, the protrusion 350A may be provided on a boundary surface between the first stepped portion 310A and the second stepped portion 320A. The protrusion 350A may be spaced apart from each of the first lead terminal 120_1 and the second lead terminal 120_2. The protrusion 350A may extend in the second direction D2 perpendicular to a direction in which the first lead terminal 120_1 and the second lead terminal 120_2 are spaced apart.

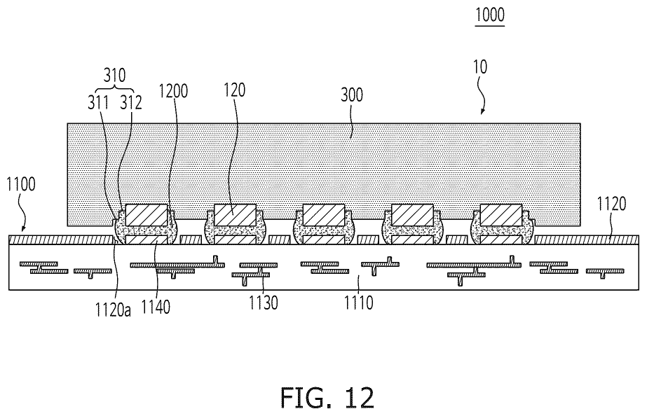

FIG. 12 illustrates a part of an electronic device including the semiconductor package according to some example embodiments of the present disclosure.

Referring to FIG. 12, an electronic device 1000 according to some example embodiments of the present disclosure may include a substrate 1100, a semiconductor package 10, and a plurality of joints 1200.

The substrate 1100 may include a substrate base 1110, a solder resist 1120, a wiring pattern 1130, and a plurality of connection pads 1140.

The substrate 1100 may be a printed circuit board (PCB). In some example embodiments, the printed circuit board may be a multilayer printed circuit board having a substrate base 1110 in which a plurality of base layers are laminated. In some example embodiments, each of the plurality of base layers forming the substrate base 1110 may be formed of at least one material selected from phenol resin, epoxy resin, and polyimide.

The solder resist 1120 may be disposed on an upper surface of the substrate base 1110. The solder resist 1120 may be coated on the substrate base 1110 with a predetermined (or desired or given) thickness. The solder resist 1120 may include an opening 1120a to expose a partial region. The plurality of connection pads 1140 may be exposed through the opening 1120a. In some example embodiments, an area of the opening 1120a may be greater than an area of each of the plurality of connection pads 1140. That is, each of the plurality of connection pads 1140 may be spaced apart from the solder resist 1120.

The wiring pattern 1130 may be formed of, for example, ED copper foil, RA copper foil, stainless-steel foil, aluminum foil, ultra-thin copper foil, sputtered copper, or copper alloys. Conductive vias may electrically connect the wiring patterns 1130. The conductive vias may be formed to penetrate at least one of the plurality of base layers.

The plurality of connection pads 1140 may be disposed on the upper surface of the substrate 1100. The plurality of connection pads 1140 may be exposed through the opening 1120a of the solder resist 1120. The plurality of connection pads 1140 may be portions where the semiconductor package 10 and the substrate 1100 are electrically connected. For example, the wiring pattern 1130 and the plurality of connection pads 1140 may be formed of copper, nickel, stainless steel, or beryllium copper.

The semiconductor package 10 may be disposed on the substrate 1100. Each of the plurality of lead terminals 120 may correspond to a connection pad 1140 of the plurality of connection pads 1140. The semiconductor package 10 may be mounted on the substrate 1100 and may be electrically connected to the substrate 1100. For example, lead terminals among the plurality of lead terminals 120 that perform input/output terminal functions may be electrically connected to the wiring pattern 1130 of the substrate 1100.

The plurality of joints 1200 may be disposed on the substrate 1100. The plurality of joints 1200 may electrically connect the plurality of lead terminals 120 of the semiconductor package 10 and the plurality of connection pads 1140 of the substrate 1100. The plurality of joints 1200 may include a conductive material. For example, the plurality of joints 1200 may include solder paste.

The plurality of joints 1200 may flow into the first stepped portion 310 of the semiconductor package 10. The plurality of joints 1200 may contact the plurality of lead terminals 120 of the semiconductor package 10. For example, each of the plurality of joints 1200 may contact the lower surface 120_BS, the first side surface 123, and the second side surface 124 of a corresponding one of the plurality of lead terminals 120.

An upper or top surface of one or more of the plurality of joints 1200 may be positioned at a level higher (e.g., with respect to the orientation in FIG. 12) than the first stepped surface 311. At least some of the plurality of joints 1200 may be positioned between the first stepped surface 311 and the second stepped surface 312. At least some of the plurality of joints 1200 may overlap horizontally with a connecting surface between the first stepped surface 311 and the second stepped surface 312. In some example embodiments, at least some of the plurality of joints 1200 may contact the second stepped surface 312.

Because each of the plurality of joints 1200 has an increased contact area with each of the plurality of lead terminals 120, an electronic device according to some example embodiments of the present disclosure may improve mechanical coupling force and increase durability against thermal and/or mechanical stress.

Hereinafter, with reference to the drawings, a manufacturing method of the semiconductor package according to some example embodiments of the present disclosure will be described.

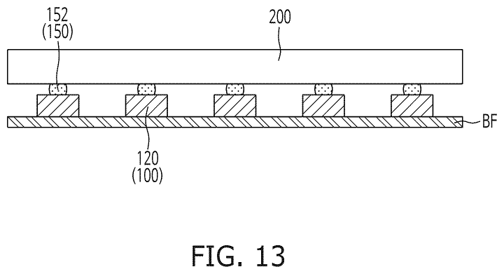

FIGS. 13, 14, 15, and 16 illustrate a manufacturing method of the semiconductor package according to some example embodiments of the present disclosure.

Referring to FIG. 13, the lead frame 100 may be attached on a base film BF. The lead frame 100 may be fixed on or mounted or otherwise coupled to the base film BF.

The semiconductor chip 200 may be disposed on the lead frame 100. For example, the semiconductor chip 200 may be mounted on the lead frame 100 through the plurality of solder bumps 150. The plurality of solder bumps 150 may be disposed on one surface of the semiconductor chip 200. The semiconductor chip 200 may be mounted such that the plurality of solder bumps 150 face the lead frame 100. For example, the semiconductor chip 200 may be mounted on the lead frame 100 in a flip-chip manner. For example, the second solder bumps 152 disposed on a surface of the semiconductor chip 200 may be mounted on the lead terminals 120.

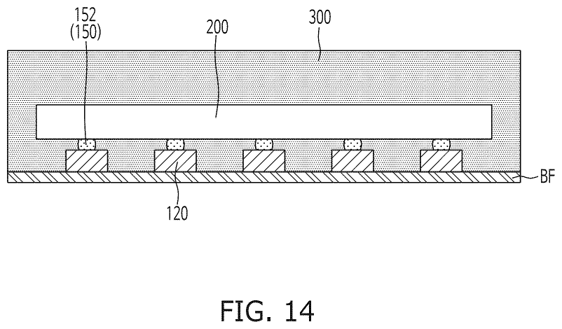

Referring to FIG. 14, the mold part 300 may be formed on the base film BF. The mold part 300 may cover each of the lead frame 100, the plurality of solder bumps 150, and the semiconductor chip 200 and may be between adjacent lead terminals 120 and adjacent solder bumps 150, and contact side surfaces of the lead terminals 120 and the solder bumps 150. The mold part 300 may integrate the lead frame 100 and the semiconductor chip 200. The mold part 300 may not cover partial regions of the plurality of lead terminals 120. The mold part 300 may expose partial regions of the plurality of lead terminals 120 so that the plurality of lead terminals 120 are connected to a substrate. The mold part 300 may be formed in a substantially hexahedral shape. For example, the mold part 300 may include an insulating material such as an epoxy mold compound (EMC). The mold part 300 may be formed by injection-molding the epoxy mold compound (EMC).

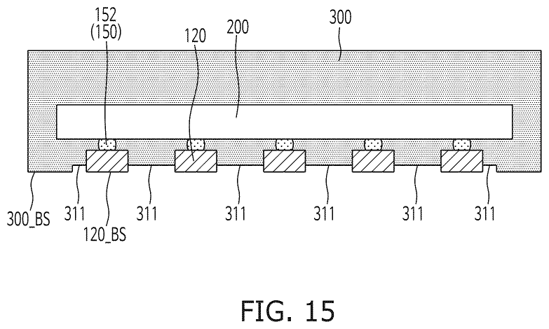

Referring to FIG. 15, the base film BF may be removed. As a result, the lower surface 300_BS of the mold part 300 and the lower surface 120_BS of the plurality of lead terminals 120 may be exposed. The side surfaces of the plurality of lead terminals 120 may be covered by the mold part 300.

A part of the mold part 300 may be removed to form the first stepped surface 311. A part of the mold part 300 may be removed to a predetermined (or desired or given) depth from the lower surface 300_BS of the mold part 300. The lower surface 300_BS of the mold part 300 and the first stepped surface 311 may have a step therebetween. For example, the first stepped surface 311 may have a flat or planar shape.

The first stepped surface 311 may be removed so as to expose side surfaces of each of the plurality of lead terminals 120. For example, the first stepped surface 311 may be a continuous surface extending over the plurality of lead terminals 120.

The first stepped surface 311 may be formed by performing laser ablation on a part of the lower surface 300_BS of the mold part 300. The lower surface 300_BS of the mold part 300 may be patterned by irradiating laser. However, this is merely an example, and the first stepped surface 311 may also be formed through a process such as micro-milling.

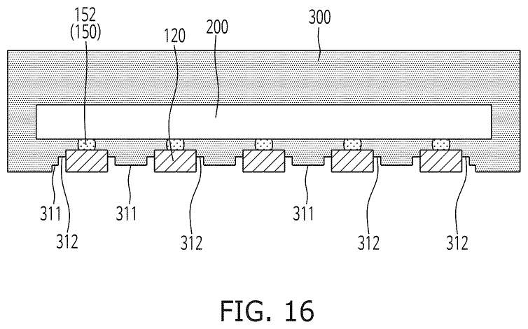

Referring to FIG. 16, a part of the mold part 300 may be removed to form the second stepped surface 312. A part of the mold part 300 may be removed by a predetermined depth from the first stepped surface 311. The first stepped surface 311 and the second stepped surface 312 may have a step therebetween. For example, the second stepped surface 312 may have a flat shape or planar.

The second stepped surface 312 may be formed at a position adjacent to side surfaces of each of the plurality of lead terminals 120. For example, the second stepped surface 312 may be formed along side surfaces of each of the plurality of lead terminals 120. The second stepped surface 312 may further expose side surfaces of the plurality of lead terminals 120.

The second stepped surface 312 may be formed by performing laser ablation on a part of the first stepped surface 311. The first stepped surface 311 may be patterned by irradiating laser. However, this is merely an example, and the second stepped surface 312 may also be formed through a process such as micro-milling.

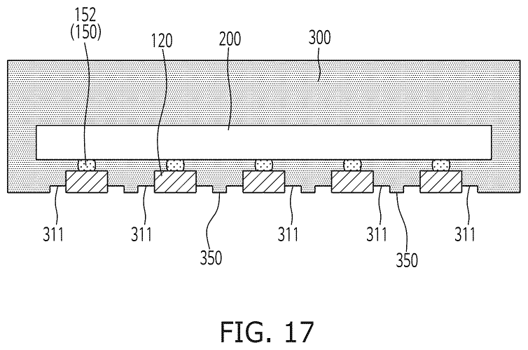

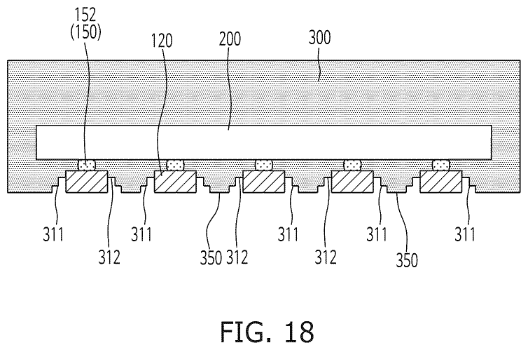

FIGS. 17 and 18 illustrate a manufacturing method of the semiconductor package according to some example embodiments of the present disclosure.

Referring to FIG. 17, a part of the mold part 300 may be removed to form the first stepped surface 311. A part of the mold part 300 may be removed to a predetermined depth from the lower surface 300_BS of the mold part 300. The first stepped surface 311 may be removed so as to expose side surfaces of each of the plurality of lead terminals 120. For example, the first stepped surface 311 may be formed at a position adjacent to side surfaces of the plurality of lead terminals 120.

A protrusion 350 may be formed between the first stepped surfaces 311 of adjacent (e.g., immediately) lead terminals 120. The protrusion 350 may be a portion of the mold part 300 that is not removed while the first stepped surface 311 is formed. A lower surface of the protrusion 350 and the first stepped surface 311 may have a step therebetween. The protrusion 350 may partition the first stepped surfaces 311 from each other.

The first stepped surface 311 may be formed by performing laser ablation on a part of the lower surface 300_BS of the mold part 300. That is, the lower surface 300_BS of the mold part 300 may be patterned by irradiating laser. However, this is merely an example, and the first stepped surface 311 may also be formed through a process such as micro-milling.

Referring to FIG. 18, a part of the mold part 300 may be removed to form the second stepped surface 312. A part of the mold part 300 may be removed by a predetermined depth from the first stepped surface 311. The second stepped surface 312 may have a flat or planar shape. The second stepped surface 312 may be formed at a position adjacent to side surfaces of each of the plurality of lead terminals 120. For example, the second stepped surface 312 may be formed along side surfaces of each of the plurality of lead terminals 120. The second stepped surface 312 may further expose side surfaces of the plurality of lead terminals 120.

The second stepped surface 312 may be formed by performing laser ablation on a part of the first stepped surface 311. The first stepped surface 311 may be patterned by irradiating laser. However, this is merely an example, and the second stepped surface 312 may also be formed through a process such as micro-milling.

According to some example embodiments, a method includes forming a mold part on a base film, the base film including a plurality of lead terminals attached thereto and a semiconductor chip connected to the plurality of lead terminals via a plurality of solder bumps; removing the base film and thereby exposing a lower surface of the mold part and the plurality of lead terminals; removing a first portion of the mold part to form a first stepped surface of the mold part; and removing a second portion of the mold part to form a second stepped surface of the mold part. According to some example embodiments, removing the first portion of the mold part comprises removing the first portion of the mold part to a first depth from the lower surface of the mold part. According to some example embodiments, a step is defined between the lower surface of the mold part and the first stepped surface. According to some example embodiments, removing the second portion of the mold part comprises removing the second portion of the mold part to a second depth from the first stepped surface. According to some example embodiments, a step is defined between the first stepped surface and the second stepped surface. According to some example embodiments, removing the second portion of the mold part forms the second stepped surface adjacent to side surfaces of each lead terminal of the plurality of lead terminals. According to some example embodiments, removing the second portion of the mold part exposes side surfaces of the plurality of lead terminals.

Example embodiments are not necessarily mutually exclusive. For example, some example embodiments may include one or more features described with reference to one or more figures, and may also include one or more other features described with reference to one or more other figures.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor package comprising:
a lead frame including a die pad and a first lead terminal spaced apart from a first side of the die pad;
a semiconductor chip on the lead frame; and
a mold part at least partially covering the lead frame and the semiconductor chip, and exposing a lower surface of the first lead terminal,
wherein the mold part includes a first stepped portion that is recessed from a lower surface of the mold part and is configured to expose a first side surface of the first lead terminal, and
the first stepped portion has a plurality of stepped surfaces.

2. The semiconductor package as claimed in claim 1, wherein the first stepped portion includes a first stepped surface having a first step with respect to the lower surface of the mold part, and a second stepped surface having a second step with respect to the first stepped surface, and
the second stepped surface contacts a side surface of the first lead terminal.

3. The semiconductor package as claimed in claim 2, wherein the first stepped surface and the second stepped surface are parallel to the lower surface of the mold part.

4. The semiconductor package as claimed in claim 2, wherein the second stepped surface is positioned at a level lower than an upper surface of the first lead terminal.

5. The semiconductor package as claimed in claim 4, wherein a distance between the second stepped surface and the upper surface of the first lead terminal is greater than or equal to 1 μm.

6. The semiconductor package as claimed in claim 4, wherein the first lead terminal has a first thickness, and
a distance between the lower surface of the mold part and the first stepped surface is less than or equal to half of the first thickness.

7. The semiconductor package as claimed in claim 4, wherein a width of the second stepped surface is less than or equal to 50 μm.

8. The semiconductor package as claimed in claim 2, wherein the lead frame further includes a second lead terminal on the first side of the die pad and spaced apart from a second side surface of the first lead terminal, the second side surface being opposite the first side surface of the first lead terminal,
the mold part includes a second stepped portion that is recessed from the lower surface of the mold part and is configured to expose a side surface of the second lead terminal, and
the second stepped portion includes a plurality of stepped surfaces.

9. The semiconductor package as claimed in claim 8, wherein the second stepped portion includes a third stepped surface at a same level as the first stepped surface, and a fourth stepped surface at a same level as the second stepped surface, and
the fourth stepped surface contacts a side surface of the second lead terminal.

10. The semiconductor package as claimed in claim 9, wherein the mold part further includes a protrusion that is configured to separate the first stepped portion and the second stepped portion, and
the protrusion includes a protrusion surface that is coplanar with the lower surface of the mold part.

11. The semiconductor package as claimed in claim 8, wherein the first lead terminal includes a first surface facing the die pad and a second surface opposite the first surface, and
in a plan view, the second stepped surface is configured to at least partially surround the first surface, a first side surface, and a second side surface of the first lead terminal, and the first stepped surface is configured to at least partially surround the second stepped surface.

12. The semiconductor package as claimed in claim 1, further comprising:
first solder bumps between the semiconductor chip and the die pad; and
second solder bumps between the semiconductor chip and the first lead terminal.

13. A semiconductor package comprising:
a lead frame including a die pad and a plurality of lead terminals at a first side of the die pad and spaced apart from each other;
a semiconductor chip on the lead frame; and
a mold part on the lead frame and the semiconductor chip, and exposing at least a portion of a lower surface of each of the plurality of lead terminals,
wherein the mold part includes,
a first stepped surface having a first step with respect to the lower surface of the mold part and around the plurality of lead terminals; and
a second stepped surface having a second step with respect to the first stepped surface and contacting a side surface of at least one of the plurality of lead terminals.

14. The semiconductor package as claimed in claim 13, wherein each of the plurality of lead terminals includes a first surface facing the die pad and a second surface opposite the first surface, and
the second stepped surface contacts the first surface.

15. The semiconductor package as claimed in claim 14, wherein in a plan view, the second stepped surface is configured to at least partially surround the first surface, a first side surface, and a second side surface of each of the plurality of lead terminals, and the first stepped surface is configured to at least partially surround the second stepped surface.

16. The semiconductor package as claimed in claim 13, wherein the mold part further includes a protrusion configured to protrude from a portion of the first stepped surface, and
the protrusion includes a protrusion surface that is coplanar with the lower surface of each of the plurality of lead terminals.

17. The semiconductor package as claimed in claim 13, wherein the first step is less than or equal to half of a thickness of a lead terminal of the plurality of lead terminals, and
a sum of the first step and the second step is less than the thickness of a lead terminal of the plurality of lead terminals.

18. The semiconductor package as claimed in claim 13, wherein the mold part further includes an inclined surface that is configured to connect the first stepped surface and the second stepped surface.

19. An electronic device comprising:
a substrate including a plurality of connection pads;
a semiconductor package on the substrate; and
a plurality of joints configured to connect the substrate and the semiconductor package,
wherein the semiconductor package includes,
a lead frame including a die pad and a plurality of lead terminals spaced apart from a first side of the die pad;
a semiconductor chip on the lead frame; and
a mold part at least partially covering the lead frame and the semiconductor chip,
wherein the mold part includes,
a first stepped surface having a first step with respect to lower surfaces of the plurality of lead terminals and at least partially around the plurality of lead terminals; and
a second stepped surface having a second step with respect to the first stepped surface and contacting a side surface of at least one of the plurality of lead terminals, and
one or more of the plurality of joints are at a level higher than the first stepped surface.

20. The electronic device as claimed in claim 19, wherein one or more of the plurality of joints contact the second stepped surface.
